(19) United States
(12) Patent Application Publication
(10) Pub. No.: US 2002/0017906 A1
(43) Pub. Date: Feb. 14, 2002

(54) Electromigration early failure distribution in submicron interconnects

(76) Inventors: Paul S. Ho, Austin, TX (US); Martin Gall, Austin, TX (US)

Correspondence Address: ERIC B. MEYERTONS, CONLEY, ROSE & TAYON, P.C., P.O. BOX 398, AUSTIN, TX, 78767-0398, US

(21) Appl. No.: 09/837,858

(22) Filed: Apr. 17, 2001

Related U.S. Application Data
(60) Provisional application No. 60/197,916, filed on Apr. 17, 2000.

(51) Int. Cl. G01R 31/08

(52) U.S. Cl. 324/526

(57) ABSTRACT

A test structure and a method for detecting early failures in a large ensemble of semiconductor elements, particularly applicable to on-chip interconnects, is provided. A novel approach to gain information about the statistical behavior of several thousand interconnects and to investigate possible deviations from perfect lognormal statistics is presented. A test structure having a Wheatstone Bridge arrangement and arrays of several hundred interconnects may be used to prove that failure data does not deviate from lognormal behavior down to a cumulative failure rate of approximately one out of 20,000. Typical test structure sizes may, therefore, be extended far beyond standard test procedures to gain information about the statistical behavior of failure mechanisms and to verify the validity of the assumption that failure mechanisms follow lognormal statistical behavior.

### BACKGROUND OF THE INVENTION

1. Field of the Invention

This invention relates to reliability testing of semiconductor elements, and more particularly, to a reliability testing method and a test structure for early failure detection in semiconductor elements.

2. Description of the Related Art

On-chip metal interconnections in semiconductor devices operate at relatively high current density which may cause these interconnections to be particularly susceptible to electromigration failure. Electromigration (“EM”) is the diffusion of atoms in a metal film or line caused by momentum transfer from the current-carrying electrons to atoms of the metal film or line. High current density conditions may cause diffusion of a sufficient number of metal atoms to create either a void or an accumulation of atoms in regions of the interconnection. Consequently, failure of the device may result from an open circuit caused by a void within an interconnection. An accumulation of atoms may also cause failure of an interconnect by increasing the local dimension of an element of the device which may then cause a connection, or a short circuit, to an adjacent interconnect.

Early failures, such as failure caused by electromigration, determine and limit the reliability of on-chip interconnects. The prevention of electromigration failures is particularly important for successful device fabrication using advanced materials, such as copper, aluminum/copper alloys, and low dielectric constant (k) materials. Therefore, early failure detection is becoming increasingly critical for effective evaluation of chip reliability of advanced semiconductor devices. The term “early” or “extrinsic” failure by electromigration describes the occurrence of a premature failure which is not consistent with the normal, monomodal failure distribution. Analysis of data from accelerated failure tests, however, are commonly performed under the assumption that only one failure mode is operative throughout a broad temperature and current range for both accelerated test and device operation conditions. Furthermore, all acquired failure distributions are assumed to follow lognormal statistics and failure data are extrapolated to predict early failures. The validity of these assumptions may be impossible to assess unless the sample size of typical test runs is considerably increased to allow accurate detection of early failures.

Formation of defects in interconnect lines may also occur due to stress-induced void formation. In general, the processing of an integrated circuit device may include a number of high temperature annealing steps. These annealing steps may cause a number of non-conductive regions (e.g., voids) to appear within metal layers, especially interconnect layers. The voids are believed to occur due to the differential thermal expansion of the metal layers during the anneal process. During the heating phase of an anneal process, metal materials will tend to expand. Each metal has its own expansion rate, based on its coefficient of thermal expansion. As the metals are cooled the metal layers will tend to contract. This differential expansion and contraction may cause internal stresses within the metal layers. These internal stresses may be relieved by the formation of voids within the metal layers. Stress-induced void formation may be a problem for many metals, especially copper and aluminum.

Typical reliability tests use an ensemble of about 50-100 test elements. These tests generally determine the mean time to failure for the test elements. Examples of typical reliability test methods are illustrated in U.S. Pat. Nos. 5,057,441; 5,264,377; 5,514,974; 5,532,600; 5,760,595; 5,878,053, and 5,900,735. Each of these patents is incorporated by reference as if fully set forth herein. While the mean time to failure methodology is straightforward, this type of testing may not accurately measure early failures because the first failure may occur much earlier than the mean time to failure. For example, in a test structure of 50 elements, the first failure occurs when 2%, or 1 of 50, of the elements fail. On the other hand, the mean time to failure does not occur until 50%, or 25 of 50, of the elements fail. The extrapolation of the data in the 2 to 50% range to below 2% may not be accurate because early failures may be induced by a different mechanism, and thus may exhibit different statistical behavior.

Additionally, as device density and performance continue to improve in integrated circuits, on-chip interconnectivity is becoming increasingly complex with larger numbers of interconnect elements between more levels of the device. A full-scale device, such as a state-of-the-art microprocessor or memory chip, may contain up to several million interconnects and each interconnect may be a potential failure link. A test structure should, therefore, contain a comparable number of test structures to accurately simulate the reliability of actual on-chip interconnectivity. Only a few studies, however, have been performed which extend the test sample size beyond the typical number of 50-100 failure units.^{1,2}

Early failure detection for on-chip interconnects is, therefore, inherently difficult because it requires testing a very large ensemble of elements and detecting the first few failures in such an ensemble. As the number of interconnections per test device increases, the measured voltage across the test ensemble increases. Therefore, the detection of a small resistance change caused by an electromigration failure is limited in large array devices by the resolution limit associated with this small resistance. Consequently, development of a test structure design and a method to detect early failures in a large ensemble of semiconductor elements is desirable in order to successfully determine on-chip interconnect reliability.

### SUMMARY

A test structure and a method for detecting early failures in a large ensemble of semiconductor elements, particularly applicable to on-chip interconnects, may in large part solve the problems described above. A novel approach to gain information about the statistical behavior of several thousand interconnects and to investigate possible deviations from perfect lognormal statistics is presented. A test structure having a Wheatstone Bridge arrangement and arrays of several hundred interconnects may be used to obtain data corresponding to a cumulative failure rate of approximately 1 out of 20,000. Typical test structure sizes may, therefore, be extended far beyond current test procedures to gain information about the statistical behavior of failure mechanisms and to verify the statistical assumption for extrapolating failure data. A large array Wheatstone Bridge test structure may also be used for process and quality control purposes. By using this structure and testing method to test intermediate and end product wafers for early failures, fabrication processes may be adjusted to increase the yield of semiconductor devices.

In an embodiment, a Wheatstone Bridge layout may be incorporated into a test structure for early failure detection. The Wheatstone Bridge circuit layout was originally designed to measure the resistance of an unknown device. A Wheatstone Bridge typically comprises four resistors connected in parallel and series. As opposed to measuring the current passing through two points in the circuit, voltage imbalance across the circuit may be monitored during a failure test. The initial voltage imbalance is usually small enough to prevent improper current settings in the two branches of the bridge. Initial resistance values for each resistor differ by only a few percent at the one sigma level. Therefore, a resistance imbalance in the two branches may be calculated which corresponds to a difference of only a few percent in stressing current density.

In an embodiment, each resistor of the Wheatstone Bridge circuit may be designed as an array of semiconductor elements, such as interconnects. The semiconductor elements may be arranged in a number of basic units, wired in a parallel and series arrangement. Therefore, each array may include several hundred semiconductor elements which may then be tested simultaneously in a single test structure. A layout incorporating interconnect arrays in a series/parallel arrangement, and a wiring scheme incorporating the well-known Wheatstone Bridge, may provide enhanced sensitivity, increased sample size, and considerably reduced testing time.

In an embodiment, a basic unit includes five Metal 2 (“M2”) interconnects in parallel. These basic units may be used as a test structure or may be repeated to form single array test structures and multiple array Wheatstone Bridge test structures. The metallization scheme employed may be a multi-layer stack, such as Ti/TiN/Al(Cu)/TiN, however other metals (e.g., copper) and dielectric materials may also be evaluated using this structure. In an embodiment, copper interconnects may be used. Copper interconnects may be produced using any standard techniques for producing copper interconnect lines, (e.g., using a damascene process). Vias may connect the interconnects between two levels on each end of the interconnects, and a test current may be supplied through wire leads. By keeping one level of interconnects well below the critical length, electromigration failure may be induced in a second level only.³ This basic unit may then be repeated in series to build a large interconnect array with M2 segments as possible failure links. For example, by wiring 96 of basic units that include five M2 segments, a large parallel/series array of 480 interconnects may be generated. Four of these arrays may be arranged into a Wheatstone Bridge layout to increase the number of test structures in the test ensemble.

In an embodiment, electromigration tests and stress-induced void testing may be performed on test structures containing one basic unit of five M2 interconnects, an array of basic units, as well as a Wheatstone Bridge device composed of four large parallel/series arrays. The methodology and test structures may be demonstrated through electromigration testing and stress-induced void formation, but may also be applied to other types of reliability tests for on-chip interconnects, e.g. extrusion failure and adhesion loss. For small test structures, resistance may be monitored over time and the occurrence of a resistance increase may be used to determine the time to failure. For Wheatstone Bridge devices, voltage imbalance may be monitored, and any change in the measured Δ V signal may be used to determine the time to failure. Compared to accelerated failure testing, moderate current density and temperature conditions may be used to test these devices. Plots of the test data may be generated by using statistical analysis techniques as described by Nelson.⁶

One advantage of a test structure having a large array of semiconductor elements in a Wheatstone Bridge arrangement is that a large number of interconnects may be tested at one time. For example, eight Wheatstone Bridge circuits, each having four large array resistors, may be tested simultaneously. Each large array resistor may, in turn, contain 96 basic units of five M2 interconnects. Therefore, the total number of interconnects in a test may be 8×4×96×5, or 15360. The cumulative failure that may be reached in using this test structure is 6.51×10⁻⁵ (F=1/15360) or 0.00651%. In comparison, a cumulative failure regime of only 1×10⁻², or 1%, may be reached using current testing structures.

Another advantage of a large array Wheatstone Bridge test structure is that the experimental time may also be considerably reduced since the failure of just one interconnect determines the failure of the entire Wheatstone Bridge device. For example, a four-array Wheatstone Bridge device may fail at about 300 hours which is approximately a six-fold decrease in the time to fail observed for current test structures. Similarly, the experimental procedure may also be significantly simplified by using a large array Wheatstone Bridge device. To test the number of one-interconnect test structures that may be incorporated in one large array Wheatstone Bridge test structure, it would be necessary to run about 128 ovens at the same time which is impractical, if not impossible, from an experimental point of view.

A large array Wheatstone Bridge test structure and testing method may also provide a more sensitive and accurate early failure detection method. Using a standard test structure and procedure, an experiment conducted on 1920 interconnects in series to determine the first fail, or the fail of the weakest interconnect, would require measurement of a total resistance of approximately 1920×18Ω, or 34560Ω. A void, on the other hand, may only cause a resistance change of approximately 0.1Ω. Therefore, detecting this resistance may be very difficult to achieve because an accuracy of 0.1/34560, or 2.9×10⁻⁶, is required. The Wheatstone Bridge arrangement, however, only monitors the resistance imbalance of the four array device, which may be on the order of several ohms, resulting in an increase in detection level on the order of 10000 over a series arrangement.

The advantages of a large array Wheatstone Bridge test structure may also provide benefits for process and quality control of semiconductor fabrication. By incorporating this test structure and testing method on process wafers, intermediate and end product wafers may be tested for early failures, and fabrication processes may be adjusted to increase the yield of semiconductor devices. For example, by rapidly testing hundreds of semiconductor elements in one Wheatstone Bridge device, a fabrication process may be evaluated quickly and adjustments to the processing conditions may be made before many product wafers are lost. The simplicity of the large array Wheatstone Bridge testing method may also enable frequent testing of intermediate product wafers to determine if the process is drifting from optimum operating conditions. The sensitivity and accuracy of the large array Wheatstone Bridge test structure also contributes to an early failure test for process wafers that is more reliable than currently available testing methods.

The experiments conducted using the test structures described above prove that early fails do not occur down to a cumulative failure, F, of 6.51×10⁻⁵. Additionally, all data are observed to follow a lognormal behavior, and deviations indicative of an early fail mechanism may be detected.

### BRIEF DESCRIPTION OF THE DRAWINGS

Other objects and advantages of the invention will become apparent upon reading the following detailed description and upon reference to the accompanying drawings in which:

FIG. 1 depicts a schematic diagram of a Wheatstone Bridge circuit wiring arrangement;

FIG. 2 depicts a top view of a basic unit, wherein the basic unit includes five interconnects in parallel connected to another metal level by vias;

FIG. 3 depicts a side view of a basic unit, wherein the basic unit includes five interconnects in parallel connected to another metal level by vias;

FIG. 4 depicts a schematic diagram of a resistor of a Wheatstone Bridge circuit, wherein a number of basic units are connected in parallel/series arrangement forming a large array of interconnects;

FIG. 5 depicts a plot of the change in voltage over time in a large array Wheatstone Bridge test structure;

FIG. 6 depicts a plot of cumulative failure distributions versus time to fail for a large array Wheatstone Bridge test structure; and

FIG. 7 depicts a plot of deconvoluted failure distributions of cumulative failure distribution plots.

While the invention is susceptible to various modifications and alternative forms, specific embodiments thereof are shown by way of example in the drawings and will herein be described in detail. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

### DETAILED DESCRIPTION OF THE PREFERRED EMBODIMENTS

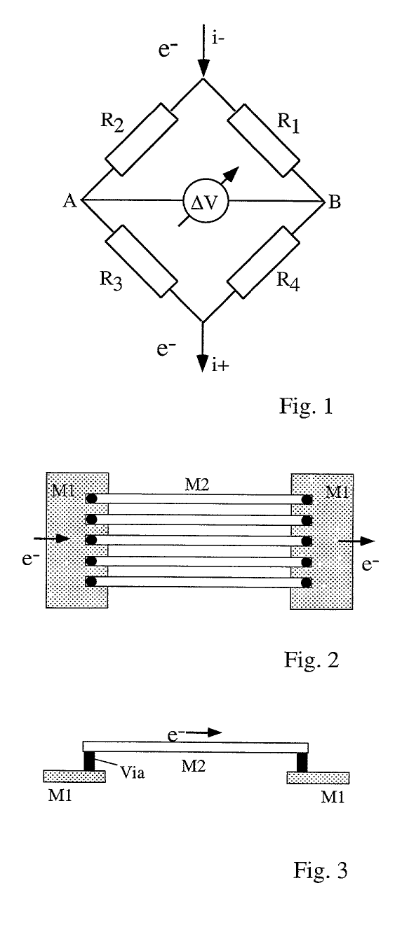

Turning to the drawings, FIG. 1 shows a wiring scheme according to a Wheatstone Bridge technique. As such, four resistors (R1, R2, R3, and R4) may be connected in parallel and series. Initially, the resistance values for each of the resistors may be measured. Typically the initial resistance values for each resistor differ by only a few percent at the one sigma level. During an electromigration experiment, the voltage imbalance ²V between the points A and B may be monitored while current i−, i+ is passing through the two branches of the circuit. An initial voltage imbalance may be small enough to prevent improper current settings in the two branches of the bridge. The voltage imbalance in the two branches leads to a difference of only a few percent in stressing current density.

Each resistor of the Wheatstone Bridge circuit may include an array of basic units. Each basic unit may include N groups of interconnects connected in parallel with each group containing M elements in series. FIG. 2 depicts a top view of an embodiment of a basic unit having five Metal 2 (“M2”) interconnects in parallel connected to a Metal 1 (“M1”) level. FIG. 3 depicts a side view of the basic unit of FIG. 2. In this case, N=5 and M=1. Thus for each basic unit, there are N×M elements. The Metal1/Via/Metal2 (M1/Via/M2) chains may be designed to be approximately 5 μm long on the lower M1 level and approximately 100 μm long on the upper M2 level. The metallization scheme employed may be a multi-layer stack of Ti/TiN/Al(Cu)/TiN, however, other metals and dielectric materials may also be included in such a structure. Metal line widths and via sizes may be approximately 0.6 μm. By keeping the lower level interconnects well below the critical length, electromigration failure may be induced in the upper level only.³

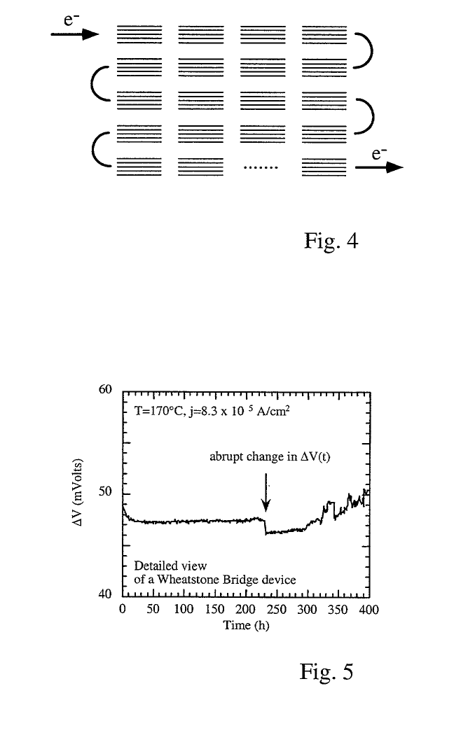

FIG. 4 depicts an array of basic units arranged in a large array parallel/series wiring scheme. For example, a basic unit may be repeated 96 times in series to build a large interconnect array of 480 M2 segments which may potentially exhibit electromigration failure. Therefore, a Wheatstone Bridge test structure comprising four large array resistors, each having 480 interconnect elements with five basic units connected in parallel and 96 elements connected in series, may be used for reliability testing. In this test structure, 4×480, or 1920, elements may be tested simultaneously in one ensemble for possible early failure.

Basic units, large arrays of interconnects, and large array Wheatstone Bridge devices may be tested individually or simultaneously in electromigration failure experiments. In one test run, a total of 32 basic units with five interconnects each, 13 samples with 480-interconnect arrays, and eight Wheatstone Bridge devices were tested simultaneously. Therefore, the total number of interconnects for this single test run was 21,760. Experimentation may be conducted at moderate ambient temperature and current density conditions, such as 170° C. and 8.3×10⁵ A/cm², respectively.

During an experiment, the resistance across the structure may be monitored for the basic units and single large array structures, and the criterion for failure for the basic units and array structures may be the time at which the first discernible resistance increase may be detected. The voltage drop Δ V across a large array Wheatstone Bridge may be monitored during an experiment, and the criterion for failure for the large array Wheatstone Bridge devices may be the time to first discernible voltage imbalance change ΔV(t). The choice of criterion in determination of failure accounts for the incubation time during which copper diffusing past the critical length is the dominating failure mechanism at operating conditions.^{4,5} The end of the incubation time signals the onset of aluminum drift concurrent with void formation and resistance/voltage changes.

A detailed plot of the voltage imbalance in a Wheatstone Bridge device as a function of time, ΔV(t), is depicted in FIG. 5. An initial voltage decrease may be due to commonly encountered annealing effects and coarsening of Al₂Cu precipitates which reduce the resistance of each interconnect. During the incubation time, the voltage imbalance remains constant. When void formation occurs in any of the four arrays, the voltage imbalance may change abruptly and this change may be observed on the plot. The abrupt change may cause the voltage imbalance to increase or decrease, depending on the location of the formation of the first void. In fact, about half of the devices show decreases during failure testing. As shown by the plot, the sensitivity to detect EM-induced void formation processes may be greatly enhanced by the Wheatstone Bridge technique because the monitored voltage is minimized by measuring relative, not absolute, changes. Therefore, the measurement of relative voltage imbalance may take advantage of the resolution limit capability of commercial testing systems, which is approximately 1 mV. The smallest corresponding resistance changes in the interconnect arrays can be estimated to be on the order of about 0.2Ω.

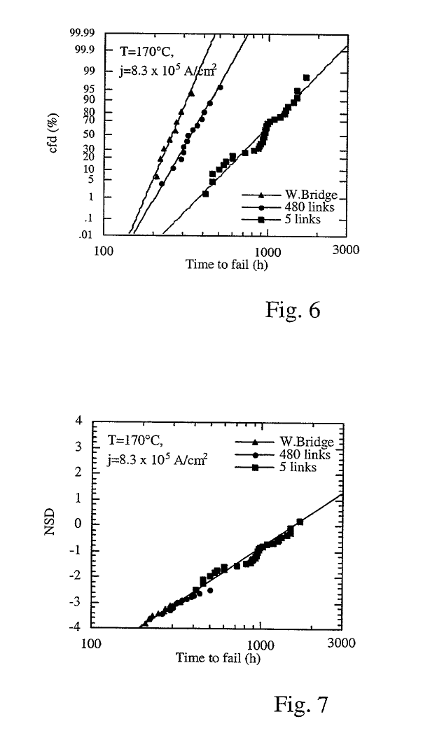

FIG. 6 depicts a plot of cumulative failure distributions (cfds) for Wheatstone Bridge devices, composed of 480-interconnect arrays, and basic units of five interconnects (links) at the above mentioned stressing conditions. FIG. 6 shows that the lifetime of a device decreases with increasing number of potential failure links. Additionally, spread in the failure distribution is shown to decrease with increasing number of potential failure links. This behavior is in accordance to the weakest link approach in which failure of the weakest link determines the lifetime of the entire assembly of multiple links. The straight lines drawn through the data in FIG. 6 are for visualization purposes only to illustrate the trend in decreasing lifetimes and spread. A lognormal fit may only be applied to a single interconnect population where the failure mechanism is typically assumed to follow lognormal statistics. When more than one failure link is tested in a chain or array, however, the behavior may not be lognormal.

The weakest link approach is only applicable if incubation time is used as the failure criterion for electromigration. After the incubation time for the failure of the first link, all other links start to fail consecutively and contribute to the total resistance increase or voltage imbalance change. Consequently, the portions of the R(t) or Δ V(t) curves corresponding to these failures may not be used for further analysis. For example, if the first of 1,920 interconnects within a Wheatstone Bridge device fails, then the information about the remaining 1,919 interconnects may have to be discarded. Discarding this data is important to statistical deconvolution of the data to the single interconnect level.

In order to assess alternate electromigration failure mechanisms (or “early” fails), the failure data as shown in FIG. 6 may be deconvoluted using conditional reliabilities. This procedure may be commonly used for reliability tests where a certain number of test devices is removed after previously set readout times.⁶ The data may conveniently be represented by a plot of Number of Standard Deviation (NSD) versus time (t). FIG. 7 depicts a plot of the three sets of data from FIG. 6 after deconvolution. Note that the failure times are unchanged, and only the failure probability changes when the data is represented on the single interconnect level. It is evident from FIG. 7 that no alternate electromigration failure mechanisms are present to a four sigma level. All data coincides on a lognormal distribution, which is represented by the straight line fit through the data. Note that the cumulative failure range may be considerably extended to F=6.51×10⁻⁵. A typical test in current use may only detect a cumulative failure range of about F=10^{-2.}

Using multi-interconnect arrays in conjunction with the well-known Wheatstone Bridge measurement technique may yield valuable information on the early fail distribution in electromigration. For the first time, a test sample size utilizing realistic multi-level interconnect metallization systems was increased to several thousand units for a single testing condition. The electromigration failure mechanism was proven to follow a lognormal behavior down to the four sigma level. Additionally, the sample size may be increased even further, and the temperature dependence of the electromigration failure population may be characterized.

It will be appreciated to those skilled in the art having the benefit of this disclosure that this invention is believed to provide a method for forming a self-aligned silicide gate conductor to a greater thickness than silicide structures subsequently formed upon source and drain regions. Further modifications and alternative embodiments of various aspects of the invention will be apparent to those skilled in the art in view of this description. It is intended that the following claims be interpreted to embrace all such modifications and changes and, accordingly, the specification and drawings are to be regarded in an illustrative rather than a restrictive sense.

### REFERENCES

The following references, to the extent that they provide exemplary procedural or other details supplementary to those set forth herein, are specifically incorporated herein by reference.

1. Muray, L. P., Rathbun, L. C., and E. D. Wolf, Appl. Phys. Lett., 53, p. 1414, 1988.

2. Hoang, H. H., Nikkel, E. L., McDavid, J. M., and R. B. Macnaughton, J. Appl. Phys., 65, p. 1044, 1989.

3. Blech, I. A., J. Appl. Phys., 47, p. 1203, 1976.

4. Kawasaki, H., and C. -K. Hu, Proc. IEEE 1996 VLSI Symp. Technol., p. 192, 1996.

5. Jawarani, D., et al., Proc. IEEE 1997 VLSI Symp. Technol., p. 39, 1997.

6. Nelson, W., Accelerated Testing, John Wiley & Sons, New York, 1990).

What is claimed is:

1. A test structure for detecting early failure of semiconductor elements formed on an integrated circuit topography, the test structure comprising a Wheatstone Bridge circuit having four resistive elements, wherein at least one of the resistive elements of the Wheatstone Bridge circuit comprises an array having an arrangement of semiconductor elements.

2. The test structure of claim 1, wherein the array further comprises a number of basic units wired in a parallel and series arrangement.

3. The test structure of claim 2, wherein the basic units comprise a number of semiconductor elements wired in a parallel and series arrangement.

4. The test structure of claim 2, wherein the basic units comprise a number of semiconductor elements wired in a parallel arrangement.

5. The test structure of claim 2, wherein the basic units comprise a number of semiconductor elements wired in a series arrangement.

6. The test structure of claim 2, wherein the number of basic units in the array is approximately greater than one hundred.

7. The test structure of claim 3, wherein the number of semiconductor elements in the basic unit is approximately greater than two.

8. The test structure of claim 3, wherein the number of basic units in the array is approximately greater than one hundred, and wherein the number of semiconductor elements in a basic unit is approximately greater than two.

9. The test structure of claim 1, wherein the early failure of the semiconductor elements is caused by electromigration-induced void or short circuit formation, stress-induced void formation, extrusion failure or adhesion loss.

10. The test structure of claim 1, wherein the test structure is configured to allow testing for void-induced defects shorting the semiconductor elements and for accumulation-induced defects coupling the semiconductor elements.

11. The test structure of claim 1, wherein the Wheatstone Bridge circuit has less than four resistive elements.

12. The test structure of claim 1, wherein at least one of the semiconductor elements is configured to be more susceptible to early failure than other semiconductor elements.

13. The test structure of claim 1, wherein the semiconductor elements comprise interconnects formed on a first level and a second level of the integrated circuit topography and connected by vias.

14. The test structure of claim 13, wherein the first level and second level of the integrated circuit are two metal levels spaced apart by a dielectric layer.

15. The test structure of claim 13, wherein the interconnects are metal lines comprised of aluminum, copper, or an aluminum/copper alloy.

16. The test structure of claim 13, wherein the interconnects on the second level of the integrated circuit topography are substantially longer than the interconnects on the first level of the integrated circuit topography.

17. The test structure of claim 13, wherein a length of the interconnects on the second level of the integrated circuit topography is approximately greater than a critical length for electromigration failure.

18. The test structure of claim 13, wherein a length of the interconnects on the first level of the integrated circuit topography is approximately less than a critical length for electromigration failure.

19. A method for detecting the early failure of semiconductor elements formed on an integrated circuit topography, comprising:
forming a test structure on the integrated circuit topography, the test structure comprising:
a Wheatstone Bridge circuit having four resistive elements, wherein at least one of the resistive elements of the Wheatstone Bridge circuit comprises an array having an arrangement of semiconductor elements.
electrically testing the Wheatstone Bridge circuit.

20. The method of claim 19, further comprising measuring an initial resistance for the resistive elements of the Wheatstone Bridge circuit.

21. The method of claim 19, further comprising passing electrical current through two branches of the Wheatstone Bridge circuit.

22. The method of claim 19, further comprising monitoring a voltage imbalance between two points in the Wheatstone Bridge circuit over time, wherein a change in the voltage imbalance indicates a time to failure.

23. The method of claim 19, wherein electrical testing of the Wheatstone Bridge circuit is carried out at an ambient temperature of less than approximately 350° C.

24. The method of claim 19, wherein electrical testing of the Wheatstone Bridge circuit is carried out at a current density of less than approximately 4×10⁶ A/cm² to approximately 5×10⁶ A/cm².

25. The method of claim 19, further comprising forming several test structures on the integrated circuit topography, and electrically testing the Wheatstone Bridge circuits simultaneously.

26. The method of claim 19, wherein forming a test structure on the integrated circuit topography further comprises forming additional semiconductor devices simultaneously on the integrated circuit topography.

27. The method of claim 26, wherein the additional semiconductor devices comprise logic or memory cells.

28. The method of claim 26, wherein the semiconductor elements of the test structure and semiconductor elements of the additional semiconductor devices have the same chemical compositions and approximately identical physical dimensions.

29. The method of claim 26, further comprising monitoring a voltage imbalance between two points in the Wheatstone Bridge circuit over time, wherein a change in the voltage imbalance signals a time to failure for the semiconductor elements of the additional semiconductor devices.

30. The method of claim 26, further comprising adjusting process conditions to alter time to failure for the semiconductor elements of the additional semiconductor devices.

31. The method of claim 19, wherein the array further comprises a number of basic units wired in a parallel and series arrangement.

32. The method of claim 31, wherein the basic units further comprise a number of semiconductor elements wired in a parallel and series arrangement.

33. The method of claim 31, wherein the basic units further comprise a number of semiconductor elements wired in a parallel arrangement.

34. The method of claim 31, wherein the basic units further comprise a number of semiconductor elements wired in a series arrangement.

35. The method of claim 31, wherein the number of basic units in the array is approximately greater than one hundred.

36. The method of claim 32, wherein the number of semiconductor elements in the basic unit is approximately greater than two.

37. The method of claim 32, wherein the number of basic units in the array is approximately greater than one hundred, and wherein the number of semiconductor elements in a basic unit is approximately greater than two.

38. The method of claim 19, wherein the early failure of the semiconductor elements may be caused by electromigration-induced void or short circuit formation, stress-induced void formation, extrusion failure or adhesion loss.

39. The method of claim 19, wherein the test structure is configured to allow testing for void-induced defects shorting the semiconductor elements and for accumulation-induced defects coupling the semiconductor elements.

40. The method of claim 19, wherein the Wheatstone Bridge circuit has less than four resistive elements.

41. The method of claim 19, wherein at least one of the semiconductor elements is configured to be more susceptible to early failure than other semiconductor elements.

42. The method of claim 19, wherein the semiconductor elements comprise interconnects formed on a first level and a second level of the integrated circuit topography and connected by vias.

43. The method of claim 42, wherein the first level and second level of the integrated circuit are two metal levels spaced apart by a dielectric layer.

44. The method of claim 42, wherein the interconnects are metal lines comprised of aluminum, copper, or an aluminum/copper alloy.

45. The method of claim 42, wherein the interconnects on the second level of the integrated circuit topography are substantially longer than the interconnects on the first level of the integrated circuit topography.

46. The method of claim 42, wherein a length of the interconnects on the second level of the integrated circuit topography is approximately greater than a critical length for electromigration failure.

47. The method of claim 42, wherein a length of the interconnects on the first level of the integrated circuit topography is approximately less than a critical length for electromigration failure.
